(19) United States
(12) Patent Application Publication
(10) Pub. No.: US 2009/0021635 A1
(43) Pub. Date: Jan. 22, 2009

(54) CAMERA MODULE

(75) Inventor: SU-JEN CHENG, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/959,188

(22) Filed: Dec. 18, 2007

(30) Foreign Application Priority Data
Jul. 20, 2007 (CN) 200710201142.4

(51) Int. Cl. H04N 5/225; H05K 5/00

(52) U.S. Cl. 348/374; 361/753; 348/E05.024

(57) ABSTRACT

A camera module includes a circuit board (11), a lens module (10) mounted on the circuit board, an electromagnetic interference shielding casing (12) surrounding the lens module and the circuit board, and a electrically conductive sheet (13) being electrically connected to the electromagnetic interference shielding casing. The circuit board forms at least one grounding tab (111) thereon. The electrically conductive sheet extends from a lateral edge of the circuit board and electrically connects the at least one grounding tab with the electromagnetic interference shielding casing. The electrically conductive sheet includes a basewall (131) connected to the circuit board and at least one sidewall (133) bending from the basewall. The at least one sidewall extends into a gap defined between the electromagnetic interference shielding casing and the lens module and electrically connected to the electromagnetic interference shielding casing.

### BACKGROUND OF THE INVENTION

1. Field of the Invention

The present invention relates generally to a camera, and more particularly to a circuit board of the camera having an electromagnetic shielding device.

2. Description of Related Art

The current trend in the electronic industry is to miniaturize electric components and circuits. Devices that conveys electrical signals, such as a wire, a printed circuit board (PCB), an integrated circuit (IC) and the like radiates and is typically susceptible to electromagnetic interference (EMI) and/or radio frequency interference (RFI). EMI and RFI cause corruption and alteration of electrical signals by such devices. Such corruption or alteration of the electrical signals in the devices is usually not tolerable. Thus, it is critical to shield these devices from each other to prevent electromagnetic and radio frequency interferences.

Referring to FIGS. 3 and 4, a general circuit board and a shielding case of a typical circuit board assembly for providing electromagnetic shielding is shown. The circuit board includes a body 1, and a number of grounding tabs 2 electrically connected to the body 1. The shielding case 3 includes a number of conductive foam portions 4. The conductive foam portions 4 are disposed in the bottom of the shielding case 3 and configured for contacting with the grounding tabs 2. After the circuit board is placed into the shielding case 3, the conductive foam portions 4 are electrically connected to the grounding tabs 2 for removing static produced on the body 1. In addition, the shielding case 3 can also protect the body 1 from EMI or RFI from outside.

However, the conductive foam portions 4 are usually manually mounted on the bottom of the shielding case 3, which may lead to errors in the installation/assembly process where the conductive foam portions 4 do not contact with the grounding tabs 2 of the shielding case 3. Thus, such shielding case cannot protect the body from EMI and RFI interferences.

Therefore, a new electromagnetic shielding device used in a camera is desired to overcome the above describe shortcomings.

### SUMMARY OF THE INVENTION

In accordance with an embodiment, a camera module includes a circuit board, a lens module mounted on the circuit board, an electromagnetic interference shielding casing enclosing the lens module and the circuit board, and an electrically conductive sheet being electrically connected to the electromagnetic interference shielding casing. The lens module includes a lens barrel, a lens unit received in the lens barrel, an image sensor being arranged at an image side of the lens unit and a lens holder surrounding the lens barrel and the image sensor. The image sensor is electrically connected to the circuit board. The circuit board forms at least one grounding tab thereon. The electrically conductive sheet extends from a lateral edge of the circuit board and electrically connects the at least one grounding tab with the electromagnetic interference shielding casing. The electrically conductive sheet includes a basewall connected to the circuit board and at least one sidewall bending from the basewall. The at least one sidewall extends into a gap defined between the electromagnetic interference shielding casing and the lens holder and electrically connects to the electromagnetic interference shielding casing.

Other advantages and novel features of the present invention will be drawn from the following detailed description of a preferred embodiment of the present invention with attached drawings, in which:

### BRIEF DESCRIPTION OF THE DRAWINGS

The present invention is described in greater detail hereinafter, by way of example only, through description of a preferred embodiment thereof and with reference to the accompanying drawing in which:

FIG. 1 is a cross-sectional view of a camera module of a preferred embodiment of the present invention;

FIG. 2 is an isometric, assembled view of the camera module of FIG. 1 viewed from another aspect;

FIG. 3 is a schematic isometric view of a general circuit board of a related circuit board assembly; and

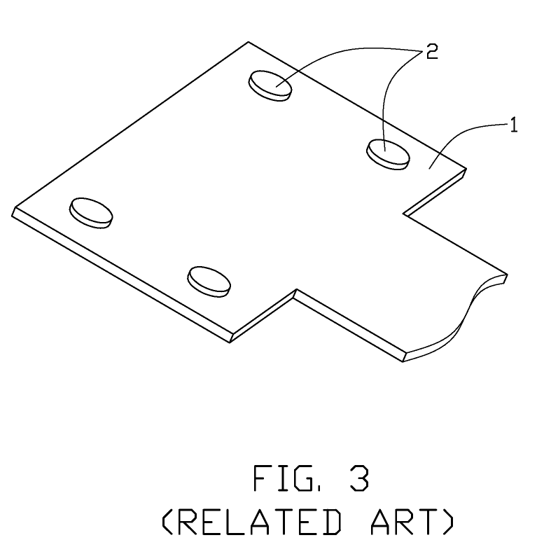

FIG. 4 is a schematic isometric view of a general shielding case for shielding the circuit board of FIG. 3.

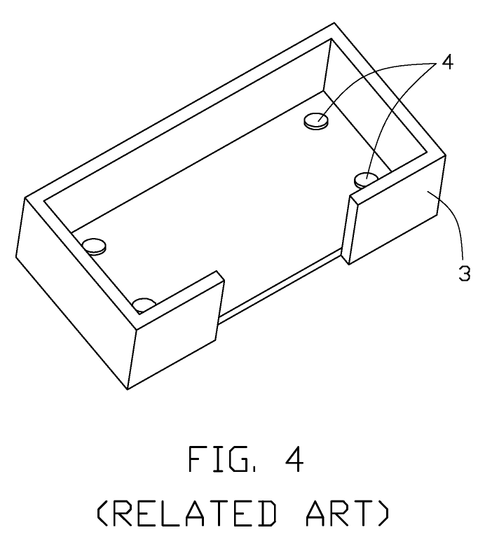

### DETAILED DESCRIPTION OF THE INVENTION

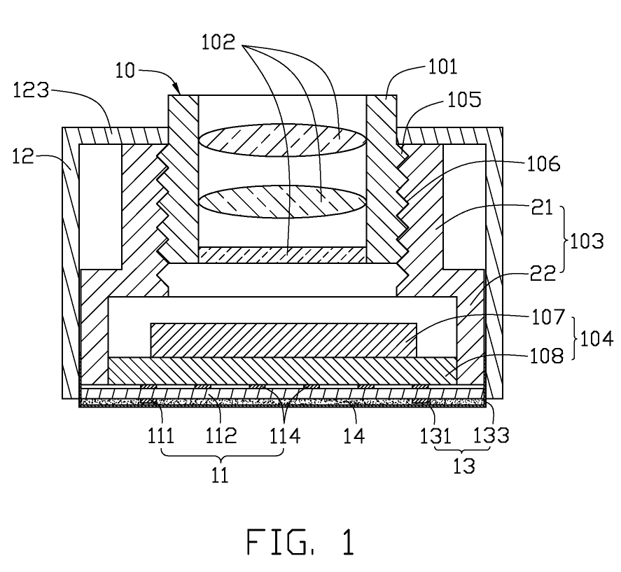

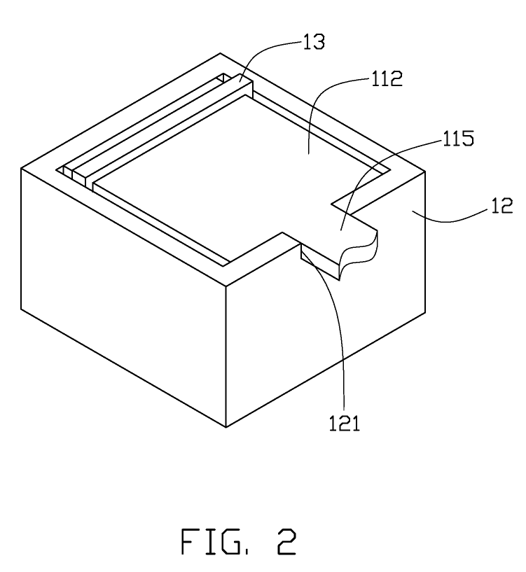

The detailed explanation of a camera module having an electromagnetic interference shielding casing 12 according to the present invention will now be made with reference to the drawing attached hereto. Referring to FIGS. 1 and 2, the camera module includes a lens module 10, a circuit board 11, an electromagnetic interference shielding casing 12, and an electrically conductive sheet 13.

The lens module 10 includes a lens barrel 101, a lens unit 102 being fixedly received in the lens barrel 101, a lens holder 103 mounted around the lens barrel 101, and an image sensor 104 arranged in the lens holder 103. The lens holder 103 is step-shaped, and includes an upper portion 21 and a lower portion 22 with a diameter larger than that of the upper portion 21. The upper portion 21 of the lens holder 103 forms an inner screw thread 106 on an inner surface thereof, and the lens barrel 101 forms an outer screw thread 105 on an outer surface thereof which threadedly engages with the inner screw thread 106 of the lens holder 103. Thus the lens barrel 101 can be easily and precisely assembled in a required initial position by adjusting relative position of the lens barrel 101 relative to the lens holder 103 when the lens barrel 101 is screwed in the lens holder 103. Further, during operation, relative rotation between the lens barrel 101 and the lens holder 103 turns to axial telescopic movement of the lens barrel 101 and the lens unit 102 through the action between the inner screw thread 106 of the lens holder 103 and the outer screw thread 105 of the lens barrel 101.

The image sensor 104 is arranged in a bottom of the lower portion 22 of the lens holder 103. In other words, the image sensor 104 is arranged at an image side of the lens unit 102. The image sensor 104 includes a substrate 108, and an image sensor chip 107 being arranged on and electrically connected to the substrate 108. The image sensor 104 is either a charge coupled device (CCD) sensor or a complementary metal oxide semiconductor (CMOS) sensor, and is controlled by a central processing unit (CPU, not shown). As the lens unit 102 moves, the CPU compares the image from the lens unit 102 with the image in the image sensor chip 107. As the lens moves to a position where the clearest image is obtained, the CPU simultaneously sends a stop signal to stop the movement of the lens unit 102.

The circuit board 11 is arranged under the lens holder 103, a size of the circuit board 11 is approximately the same as an outer size of the lower portion 22 of the lens holder 103. The circuit board 11 includes a base 112, a number of pads 114 disposed on a top surface of the base 112, a number of grounding tabs 111 disposed at an opposite bottom surface of the base 112, and a data line 115 extending form a lateral edge of the base 112. In this embodiment, the circuit board 11 is a printed circuit board (PCB) and is configured for fixing a number of electrical components (not shown) on the top surface thereof. The base 112 is made from an isolative, adiabatic, flexible material. A plurality of circuits are printed on the base 112 and are configured for conveying electrical signals between the electrical components. The pads 114 are configured for welding the electrical components onto the circuit board 11. The substrate 108 of the image sensor 104 is electrically connected to the pads 114 of the circuit board 11. The data line 115 is electrically connected to the pads 114 and configured for transmitting signals generated by the image sensor 104 to the CPU to control movement of the lens unit 102. The grounding tabs 111 are electrically connected to the circuit of the base 112, and are configured for removing a static produced by the electric components. In this embodiment, the number of the grounding tabs 111 is two.

The electromagnetic interference shielding casing 12 can be made of a metal sheet or conductive rubber. In this embodiment, the electromagnetic interference shielding casing 12 is made of conductive rubber and is configured to be a rectangular-shaped container which enclose the lens module 10 and the circuit board 11. An inner size of the electromagnetic interference shielding casing 12 is slightly larger than the size of the circuit board 11 or the outer size of the lens holder 103. A narrow gap is thus defined between the electromagnetic interference shielding casing 12 and the lens holder 103/the circuit board 11. A cutout 121 is defined in a bottom end of the electromagnetic interference shielding casing 12 for running the data line 115 therethrough. The width of the cutout 121 is essentially equal to that of the data line 115. A flange 123 extends inwardly from a top end of the electromagnetic interference shielding casing 12 and defines an opening (not labeled) in a center thereof allowing the lens barrel 101 to extend therethrough. A diameter of the opening is approximately the same as an outer diameter of the lens barrel 101, thus swing of the lens barrel 101 can be avoided during the axial telescopic movement of the lens barrel 101.

The electrically conductive sheet 13 is arranged under the circuit board 11, and is located at an opposite lateral edge of the base 112. The electrically conductive sheet 13 has a U-shape cross section, includes a basewall 131 and two sidewalls 133 bending perpendicularly from two opposite sides of the basewall 131. A length of the electrically conductive sheet 13 is approximately the same or slightly larger than an inner length of the electromagnetic interference shielding casing 12. A thickness of the sidewalls 133 is approximately equal to or slightly larger than the gap defined between the electromagnetic interference shielding casing 12 and the lens holder 103/the circuit board 11. In assembling of the circuit board 11 and the electrically conductive sheet 13 into the electromagnetic interference shielding casing 12, the basewall 131 of the electrically conductive sheet 13 is flexibly connected to the base 112 of the circuit board 11 by soldering or bonding, and is electrically connected to the grounding tabs 111 of the circuit board 11. In this embodiment, the basewall 131 of the electrically conductive sheet 13 is made of copper and is connected to the base 112 by double sided tape 14. The sidewalls 133 extend into the narrow gap between the lens holder 103 and the electromagnetic interference shielding casing 12 by interference fit, and are electrically connected to the electromagnetic interference shielding casing 12. Thus the electrically conductive sheet 13, the electromagnetic interference shielding casing 12, and the circuit board 11 are electrically connected and cooperatively form a circuit board assembly having a function of electromagnetic shielding. Alternatively, the electrically conductive sheet 13 can be integrally formed with the grounding tabs 111 of the circuit board 11, and in this situation the electrically conductive sheet 13 and the grounding tabs 111 are made from the same isolative, adiabatic, flexible material. In this case, contact between the circuit board 11 and the electrically conductive sheet 13 is firm and assembly of the circuit board assembly is simple.

Due to the electrically conductive sheet 13 being made from resilient flexible material, and the thickness of the sidewalls 133 of the electrically conductive sheet 13 being essentially equal to or slightly larger than that of the gap of the lens holder 103 and the electromagnetic interference shielding casing 12, the sidewalls 133 of the electrically conductive sheet 13 tightly contact with the electromagnetic interference shielding casing 12 after the circuit board 11 is placed into the electromagnetic interference shielding casing 12. Thus, the electrically conductive sheet 13 is electrically and firmly connected with the electromagnetic interference shielding casing 12. Therefore, the electromagnetic interference shielding casing 12 can reliably remove static of the circuit board assembly As described above, the electrically conductive sheet 13 is integral and contacts with the two grounding tabs 111. It is to be understood that there can be a number of electrically conductive sheets 13. The number of the electrically conductive sheets 13 is equal to that of the grounding tabs 111. Each electrically conductive sheet 13 connects to one of the grounding tabs 111. When the circuit board 11 is assembled to the electromagnetic interference shielding casing 17, the electrically conductive sheet 13 then connects to the electromagnetic interference shielding casing 17 in parallel or in series. The electrically conductive sheets 13, the electromagnetic interference shielding casing 17, and the circuit board 11 together forms the circuit board assembly having electromagnetic shielding function.

It can be understood that the above-described embodiment are intended to illustrate rather than limit the invention. Variations may be made to the embodiments and methods without departing from the spirit of the invention. Accordingly, it is appropriate that the appended claims be construed broadly and in a manner consistent with the scope of the invention.

What is claimed is:

1. A camera module comprising:
a lens module;
a circuit board arranged at an image side of the lens module, the circuit board forming at least one grounding tab thereon;
an electromagnetic interference shielding casing surrounding the lens module and the circuit board therein; and
an electrically conductive sheet extending from a lateral edge of the circuit board, the electrically conductive sheet electrically connecting the at least one grounding tab to the electromagnetic interference shielding casing.

2. The camera module of claim 1, wherein the lens module comprises a lens barrel, a lens unit received in the lens barrel, an image sensor arranged at the image side of the lens unit, and a lens holder surrounding the image sensor and the lens barrel.

3. The camera module of claim 2, wherein the electromagnetic interference shielding casing has a flange extending inwardly at an object side of the lens module, the flange defining an opening with a diameter being approximately the same as an outer diameter of the lens barrel for extension of the lens barrel therethrough.

4. The camera module of claim 2, wherein the lens holder is step-shaped, a first portion of the lens barrel with a relatively smaller diameter forming an inner screw thread thereon, and the lens barrel forming an outer screw thread threadedly engaging with the inner screw thread, the image sensor being received in a second portion of the lens barrel having a relatively larger diameter.

5. The camera module of claim 1, wherein the electromagnetic interference shielding casing is made one of metal and electrically conductive rubber.

6. The camera module of claim 1, wherein the circuit board comprises a base having printed circuits formed thereon, the at least one grounding tab being arranged on the base and being electrically connected to the circuits of the base.

7. The camera module of claim 1, wherein the electrically conductive sheet is made of copper and is connected to the circuit board by double sided tape.

8. The camera module of claim 1, wherein the electrically conductive sheet and the at least one grounding tab are integrally formed from the same material.

9. The camera module of claim 1, wherein the at least one grounding tab comprises a number of grounding tabs, and the at least one electrically conductive sheet has a number of electrically conductive sheets, a number of the grounding tabs being equal to that of the electrically conductive sheets, each electrically conductive sheet being electrically connected to one grounding tab.

10. The camera module of claim 1, wherein the at least one grounding tab comprises a number of grounding tabs, and the at least one electrically conductive sheet has one electrically conductive sheet being electrically connected with all of the grounding tabs.

11. The camera module of claim 1, wherein the electrically conductive sheet comprises a basewall connected to the circuit board and at least one sidewall bending from the basewall, the at least one sidewall extending into a gap defined between the electromagnetic interference shielding casing and the lens module and electrically connected to the electromagnetic interference shielding casing.

12. A circuit board assembly comprising:
a circuit board forming at least one grounding tab thereon;
a lens module mounted on the circuit board, the lens module comprising a lens barrel, a lens unit received in the lens barrel, an image sensor being arranged at an image side of the lens unit and a lens holder surrounding the lens barrel and the image sensor, the image sensor being electrically connected to the circuit board;
an electromagnetic interference shielding casing surrounding the lens module and the circuit board; and
at least one electrically conductive sheet extending from a lateral edge of the circuit board and electrically connecting the at least one grounding tab to the electromagnetic interference shielding casing, the at least one electrically conductive sheet comprising a basewall connected to the circuit board and at least one sidewall bending from the basewall, the at least one sidewall extending into a gap defined between the electromagnetic interference shielding casing and the lens holder and electrically connected to the electromagnetic interference shielding casing.
